(19) United States
(12) Patent Application Publication
(10) Pub. No.: US 2004/0104449 A1
(43) Pub. Date: Jun. 3, 2004

(54) Three- dimensional metal devices highly suspended above semiconductor substrate, their circuit model, and method for manufacturing the same

(76) Inventors: Jun-Bo Yoon, Taejon (KR); Euisik Yoon, Taejon (KR); Choong-Ki Kim, Taejon (KR); Chul-Hi Han, Taejon (KR)

Correspondence Address: Marger Johnson & McCollom, 1030 S W Morrison Street, Portland, OR, 97205, US

(21) Appl. No.: 10/473,555

(22) PCT Filed: Dec. 26, 2001
(86) PCT No.: PCT/KR01/02260

(30) Foreign Application Priority Data
Mar. 29, 2001 (KR) 2001/16404

(51) Int. Cl. H01L 21/44; H01L 21/50; H01L 29/00; H01L 23/24

(52) U.S. Cl. 257/528; 438/381; 438/106; 438/124; 257/531; 257/687

(57) ABSTRACT

Disclosed are a three dimensional metal device floated over a semiconductor substrate, a circuit thereof, and a manufacturing method thereof. A passive electric device for wireless communications and optical communications, such as a spiral inductor, a solenoid inductor, a spiral transformer, a solenoid transformer, a micro mirror, a transmission line is floated over and apart by a few ten micrometers from the semiconductor substrate. These three dimensional metal devices remarkably decrease a signal loss to the substrate, to thereby enhance the device performance, to allow a modeling of a device separated from the substrate, and to make it possible to form an integrated circuit below the device. Further, the three dimensional metal device is manufactured in a monolithic method on the integrated circuit such that it does not affect on the integrated circuit formed therebelow.

### TECHNICAL FIELD

The present invention relates to a three-dimensional metal device highly suspended above a semiconductor substrate, a circuit thereof, and a manufacturing method thereof, and more particularly, to a three-dimensional metal device, in which various passive electrical devices for radio telecommunications and optical telecommunications, such as spiral inductor, solenoid inductor, spiral transformer, solenoid transformer, micro mirror, transmission line and the like, are made from metal and are suspended above a semiconductor substrate by a few ten micrometer, for instance, 30 micrometers or more, a circuit thereof, and a manufacturing method thereof. Further, the invention is directed to a micromachining (MEMS) method, which enables to manufacture the three-dimensional metal devices which could not be manufactured by using the conventional semiconductor integration technologies, and which can be exchangeably used with the conventional semiconductor integration technologies. Moreover, the invention is directed to a new three-dimensional inductor model, which is not related with a characteristic of the substrate and is appropriate for three-dimensional inductors according to the present invention.

### BACKGROUND ART

The conventional semiconductor integration technologies start from U.S. Pat. No. 3,138,743, which was allowed to J. S. Kilby in 1964. The U.S. Pat. No. '743 discloses an integration technology of various electrical devices including passive devices on a planar semiconductor substrate. According to the U.S. Pat. No. '743, since the passive devices are integrated on a plane like circuits, i.e., on the surface of the semiconductor substrate, the chip size is very large, and also since the passive electrical devices are in contact with the substrate, parasitic effects are generated to thereby lower the performance of the passive electrical devices. This disadvantage is very serious when the passive devices are applied to radio frequency integrated circuit (RF IC) and microwave monolithic integrated circuit (MMIC) in which their importance further increases at recent years.

So, the off-chip passive electrical devices are presently being used in a lead-soldered state outside the chip. These off-chip passive electrical devices have good electrical performance but they still have disadvantages in that the system size becomes large and a cost for the assembly of the system increases.

The inductor is a representative among devices, which are difficult to integrate with the present semiconductor technologies. Since an integrated inductor manufactured for obtaining an inductance value required in a general radio frequency circuit has a size much larger than other active electric devices or passive electric devices, it occupies a large substrate area. Further, since the integrated inductor is bonded to the substrate, there occur disadvantages in that this conventional integrated inductor has a large series resistance and a small current limitation due to a parasitic effect generated between the integrated inductor and the substrate, and a limitation in a thickness (a few micrometer) of the metal interconnection line realized by the conventional integrated circuit technology. Large substrate loss and large series resistance allow the value of Q-factor that is the most important among the characteristics of the inductor to be small and the peak-Q frequency at which a maximum value of the Q-values is generated, to be lowered.

Also, upon reviewing the inductor model that is an essential element in a design of an ultra radio frequency circuit, since the conventional integrated inductor is not free from the influence of the substrate, a complicated inductor model should be used, and since the influence varies with the characteristics of the substrate, it is incorrect. These results can be reviewed through FIG. 1. FIG. 1 is a perspective view of a conventional integrated inductor 101 recorded in a paper “IEEE Transactions on Electron Devices, vol. 47, pp. 560-568, March 2000” entitled “Physical Modeling of Spiral Inductors on Silicon”, by C. P. Yue, et al.

Referring to FIG. 1, an insulating layer 2 is disposed on a silicon (Si) substrate 1, and a spiral inductor 5 is disposed on the insulating layer 2. Inner interconnection lines of the spiral inductor are leaded outside through a via 4 and a lower lead wire 3.

FIG. 2 is an equivalent circuit diagram of the integrated inductor model 102 shown in FIG. 1. Referring to FIGS. 1 and 2, the metal line itself of the spiral inductor 5 contains a series resistance (R) and an inductance component (L). A fringe capacitance C_{f} is formed between the spiral inductor 5 and the underlying lead wire 3. A capacitor Cox is formed in the insulating layer between the spiral inductor 5 and the Si substrate 1. The Si substrate contains a substrate resistance R_{Si} and a substrate capacitance C_{Si}. The aforementioned elements are connected with each other, to thereby form the conventional integrated inductor model 102. Among these components, the substrate resistance R_{Si} and the substrate capacitance C_{Si} are varied with the thickness of the substrate, material characteristic, and distribution and existence and nonexistence of a ground plane, which makes it impossible to for man independent model from the substrate.

Up to the now, there are proposed methods for enhancing the performance of the integrated spiral inductor in U.S. Pat. No. 5,539,241, U.S. Pat. No. 5,773,870 and U.S. Pat. No. 5,844,299. However, since these methods etch the substrate laid below the inductor, it is impossible to integrate circuits below the inductor, it is difficult to exchange the etch process of the substrate with the integration processes, and there may occur many problems in the package.

There are proposed another methods for decreasing capacitance (Cox of FIGS. 1 and 2) between the inductor and the substrate by interposing a thick insulating layer such as polyimide between the substrate and the inductor in U.S. Pat. No. 5,478,773 and U.S. Pat. No. 5,805,043. However, it is anticipated that these methods need an insulating layer having a thickness of a few ten micrometer or more such that the inductor does not affect the integrated circuits below the inductor. Further, these methods have limitations in that dielectric constant of the insulating layer should be very small and a process temperature for forming the insulating layer does not affect on the integrated circuits, which are manufactured below the inductor in advance.

There is proposed a further another manufacturing method in U.S. Pat. No. 6,008,102, in which an inductor is made in the form of solenoid to increase inductance per unit area and decrease signal loss. This method performs a process for forming a photoresist mold and an electroplating metal three times repeatedly to thereby manufacture a three layers-stacked solenoid inductor. This method seems to be theoretically possible but the inventor found that there are many problems by applying the method to a real process. The worst problem is that the shape of the lower photoresist mold may be transformed while the upper photoresist mold is formed. This is because the shape of the photoresist is easily transformed by heat, which can be easily understood to those skilled in the art. Thus, it is impossible to manufacture the solenoid inductor with high yield and reproducibility, and it is particularly difficult to manufacture the solenoid inductor having a core height of 20 micrometers or more.

In addition to the inductors aforementioned, trials for integrating various passive electrical devices for radio telecommunications and optical telecommunications, such as transformer, micromirror and transmission line, on a semiconductor substrate are being accelerated. However, it is the actual circumstance that there no exist a structure in which the various passive devices occupy a small area on the substrate, and have a small substrate loss and a good Q-factor, a circuit model not relating with the substrate, and a proper manufacturing method.

### DETAILED DESCRIPTION OF THE INVENTION

Accordingly, it is a technical object of the invention to provide a method for manufacturing a three-dimensional metal device in which a signal loss decreases remarkably to enhance the performance of the device, it is possible to form the device model independently from a substrate, and it becomes possible to form an integrated circuit below the device, thereby enhancing the integrity when various passive electrical devices for radio telecommunications and optical telecommunications, such as spiral inductor, solenoid inductor, spiral transformer, solenoid transformer, micro mirror, transmission line and the like, are formed from metal.

It is another object of the invention to provide a method for manufacturing a three-dimensional metal device having a metal line capable of decreasing a series resistance and extending a current limitation flowable in the three-dimensional metal device.

It is further another object of the invention to provide a method for manufacturing a micromachining capable of manufacturing a three-dimensional metal device having a good performance on a previously manufactured integrated circuit in a monolithic method, the integrated circuit being not affected by the three-dimensional metal device at all.

It is still another object of the invention to provide various metallic passive electrical devices for radio telecommunications and optical telecommunications, such as spiral inductor, solenoid inductor, spiral transformer, solenoid transformer, micro mirror, transmission line and the like.

It is further still another object of the invention to provide a new three-dimensional inductor model that is not related with the characteristic of the substrate and is proper for a three-dimensional inductor in accordance with the present invention.

To accomplish the above objects, there is provided a three-dimensional spiral inductor suspended above a substrate. The three-dimensional spiral inductor includes: a third metal layer suspended in a spiral shape; two first supporting bars connected with the underlying substrate, a bottom metal layer, or an integrated circuit on the substrate vertically from an inner end and an outer end of the spiral shaped third metal layer, for supporting the third metal layer; and any one among the substrate below the first supporting bar, the substrate and the bottom metal layer on the substrate, the substrate and the integrated circuit on the substrate, and the substrate, the integrated circuit and the bottom metal layer on the substrate.

Also, according to another aspect of the invention, there is provided a solenoid inductor. The solenoid inductor includes: at least one third metal layer suspended in a bar shape; two first supporting bars respectively connected with opposite ends of two adjacent bottom metal layers having the bar shape vertically from both ends of the third metal layer, for supporting the bar-shaped third metal layer; the bottom metal layers disposed below the first supporting bar and having the bar shape; and a substrate disposed below the bottom metal layer or the substrate and an integrated circuit on the substrate.

Further, according to further aspect of the invention, there is provided a three-dimensional solenoid inductor. The three-dimensional solenoid inductor includes: at least one fourth metal layer suspended in a bar shape; two second supporting bars connected with opposite ends of two adjacent third metal layers suspended in a bar shape vertically from both ends of the fourth metal layer, for supporting the fourth metal layer; at least one third metal layer disposed below the second supporting bar and having the bar shape; two first supporting bars vertically connected with a underlying substrate, a bottom metal layer or an integrated circuit on the substrate from both ends of the suspended solenoid inductor including the fourth metal layer, the second supporting bars, and the bar-shaped third metal layer, for supporting the suspended solenoid inductor; and any one among the substrate below the first supporting bar, the substrate and the bottom metal layer on the substrate, the substrate and the integrated circuit on the substrate, and the substrate, the integrated circuit and the bottom metal layer on the substrate.

Furthermore, according to still another aspect of the invention, there is provided a three-dimensional solenoid transformer. The solenoid transformer does not connect turns of the suspended solenoid inductor including the fourth metal layer, the second supporting bar, the third metal layer and the first supporting bar in a single strand, but divides the turns into two strands of a first turn and a secondary turn, the first turn and the secondary turn being alternatively wound to each other.

Moreover, according to further still another aspect of the invention, there is provided a three-dimensional spiral transformer. The three-dimensional spiral transformer includes: a fourth metal layer suspended in a spiral shape; two second supporting bars connected with an underlying first supporting bar vertically from both ends of the fourth metal layer, for supporting the fourth metal layer suspended in the spiral shape; a third metal layer disposed below the fourth metal layer and suspended in the spiral shape; two first supporting bars connected with a underlying substrate, a bottom metal layer or an integrated circuit disposed on the substrate vertically from both ends of the third metal layer suspended in the spiral shape, for supporting the third metal layer; the two first supporting bars vertically connected with the underlying substrate, the bottom metal layer, or the integrated circuit disposed on the substrate, for supporting the two second supporting bars; and any one among the substrate below the first supporting bar, the substrate and the bottom metal layer on the substrate, the substrate and the integrated circuit on the substrate, and the substrate, the integrated circuit and the bottom metal layer on the substrate.

Also, according to yet further still another aspect of the invention, there is provided a three-dimensional transmission line suspended above a semiconductor substrate. The three-dimensional transmission line includes: a transmission line made of a suspended third metal layer; two first supporting bars connected with the underlying substrate, a bottom metal layer, or an integrated circuit disposed on the substrate vertically from both ends of the suspended transmission line, for supporting the suspended transmission line; and any one among the substrate below the first supporting bar, the substrate and the bottom metal layer on the substrate, the substrate and the integrated circuit on the substrate, and the substrate, the integrated circuit on the substrate, and the bottom metal layer on the integrated circuit.

Also, according to another aspect of the invention, there is provided a three-dimensional micromirror suspended above a semiconductor substrate. The three-dimensional micromirror includes: a suspended metal mirror plate; at least one first supporting bar connected with the underlying substrate, a bottom metal layer, or an integrated circuit disposed on the substrate vertically from a predetermined region of the suspended metal mirror plate, for supporting the metal mirror plate; any one among the substrate below the first supporting bar, the substrate and the bottom metal layer on the substrate, the substrate and the integrated circuit on the substrate, and the substrate, the integrated circuit on the substrate, and the bottom metal layer on the integrated circuit; and at least one electrode metal layer formed in a predetermined shape on the substrate disposed below the suspended metal mirror plate.

Further, according to further another aspect of the invention, there is provided a three-dimensional inductor model suspended above a semiconductor substrate. The three-dimensional inductor model includes: a first port of which one end is grounded; a second port of which one end is grounded; resistance (R) and inductance (L) components connected in series between the other ends which are not grounded in the first port and the second port; a fringe capacitance (Cf) component connected between the other ends which are not grounded in the first port and the second port; a Cs capacitance component connected between the grounded one end of the first port and the other end which is not grounded in the first port; and the Cs capacitance component connected between the ground one end of the second port and the other end which is not grounded in the second port.

Furthermore, according to still another aspect of the invention, there is provided a method for manufacturing a three-dimensional metal device suspended above a semiconductor substrate. The method includes the steps of: (a) preparing the substrate; (b) forming a three-dimensional sacrificial mold in a three-dimensional structure having a first space extending from a bottom of the three-dimensional sacrificial mold to an upper portion thereof, and a second space connected with the first space and spaced apart from the bottom of the three-dimensional sacrificial mold; (c) filling the first and second spaces with a third metallic layer; and (d) removing the three-dimensional sacrificial mold.

Moreover, according to further still another aspect of the invention, there is provided a method for manufacturing a three-dimensional metal device suspended above a semiconductor substrate. The method includes the steps of: (a) preparing the substrate; (b) forming a three-dimensional sacrificial mold in a three-dimensional structure having a first space extending from a bottom of the three-dimensional sacrificial mold to an upper portion thereof, and a second space connected with the first space and spaced apart from the bottom of the three-dimensional sacrificial mold; (c) filling the first and second spaces with a third metallic layer; (d) again performing the step of (b) with respect to the three-dimensional sacrificial mold and an upper surface of the third metallic layer, and filling a resultant structure with a fourth metallic layer; and (e) removing all the three-dimensional sacrificial mold.

### BRIEF DESCRIPTION OF THE DRAWINGS

FIG. 1 is a perspective view of a conventional integrated inductor;

FIG. 2 is an equivalent circuit diagram of the integrated inductor model shown in FIG. 1;

FIG. 3 is a perspective view of a three-dimensional sacrificial mold (for fabrication of a three-dimensional spiral inductor) in accordance with the present invention;

FIG. 4 is a perspective view of a three-dimensional spiral inductor in accordance with the present invention;

FIG. 5 is a perspective view of a three-dimensional spiral inductor having a ground layer in accordance with the present invention;

FIG. 6 is a circuit diagram of a new three-dimensional inductor model in accordance with the present invention;

FIG. 7 is a three-dimensional spiral inductor having a patterned ground in accordance with the invention;

FIG. 8 is a perspective view of a three-dimensional sacrificial mold (for fabrication of a solenoid inductor) in accordance with the present invention;

FIG. 9 is a perspective view of a solenoid inductor in accordance with the present invention;

FIG. 10a to FIG. 10f are sectional schematic views for illustrating a process for manufacturing a three-dimensional spiral inductor and a solenoid inductor in accordance with one embodiment of the present invention;

FIG. 10g to FIG. 10j are sectional schematic views for illustrating a process for manufacturing a three-dimensional spiral inductor and a solenoid inductor in accordance with another embodiment of the present invention;

FIG. 11 is a perspective view of a suspended three-dimensional solenoid inductor in accordance with the present invention;

FIG. 12 is a perspective view of a suspended three-dimensional solenoid inductor having a ground layer in accordance with the present invention;

FIG. 13 is a perspective view of a suspended three-dimensional solenoid inductor having a patterned ground in accordance with the present invention;

FIG. 14 is a perspective view of a stack type three-dimensional spiral inductor in accordance with the present invention;

FIG. 15 is a perspective view of a suspended three-dimensional solenoid transformer in accordance with the present invention;

FIG. 16 is a perspective view of a suspended three-dimensional spiral transformer in accordance with the present invention;

FIG. 17 is a perspective view of a three-dimensional spiral inductor having two kinds of different structured lead wires in accordance with the present invention;

FIG. 18 is a perspective view of a three-dimensional micro mirror in accordance with the present invention;

FIGS. 19-29 are perspective views showing three-dimensional shapes of various structures of three-dimensional transmission line in accordance with the present invention;

FIG. 30 is a perspective view of a three-dimensional transmission line having a solenoid-shaped ground line in accordance with the present invention; and

FIG. 31 is a perspective view of a three-dimensional spiral inductor having a solenoid-shaped ground line in accordance with the present invention.

### DESCRIPTION OF SYMBOLS IN MAIN PORTIONS OF THE DRAWINGS

1: Silicon substrate

2: Insulating layer

3: Lead wire

4: Via

5: Spiral Inductor

11: Substrate

12: First metal layer

13: Bottom metal layer

14: First exposure region

15: Three-dimensional sacrificial mold

16: Second exposure region

17: First space

18: Third exposure region

19: Second space

21: Third metal layer

22: First supporting bar

23: Second metal layer

25: Fourth metal layer

26: Second supporting bar

29: Bottom ground metal layer

30: Patterned bottom ground metal layer

31: First signal electrode

33: Second signal electrode

35: First ground wall

36: First ground wing

37: Second ground wall

38: Second ground wing

39: First turns

41: Secondary turns

43: First port

45: Second port

47: Solenoid-shaped ground wire

101: Conventional integrated inductor

102: Conventional integrated inductor model

103: Three-dimensional spiral inductor

104: Three-dimensional spiral inductor having ground layer

105: New three-dimensional inductor model

106: Three-dimensional spiral inductor having patterned ground

107: Solenoid inductor

108: Suspended three-dimensional solenoid inductor

109: Suspended three-dimensional solenoid inductor having ground layer

110: Suspended three-dimensional solenoid inductor having patterned ground

111: Stack type three-dimensional spiral inductor

112: Suspended three-dimensional solenoid transformer

113: Suspended three-dimensional spiral transformer

114: Three-dimensional spiral inductor having suspended lead wire

115: Three-dimensional spiral inductor having lead wire suspended downward

116: Three-dimensional micro mirror

117-127: Three-dimensional transmission lines having various shapes

128: Three-dimensional transmission line having ground wire of solenoid shape

129: Three-dimensional spiral inductor having ground wire of solenoid shape

### BEST MODES FOR CARRYING OUT THE INVENTION

Hereinafter, preferred embodiments of the present invention are described with reference to the accompanying drawings.

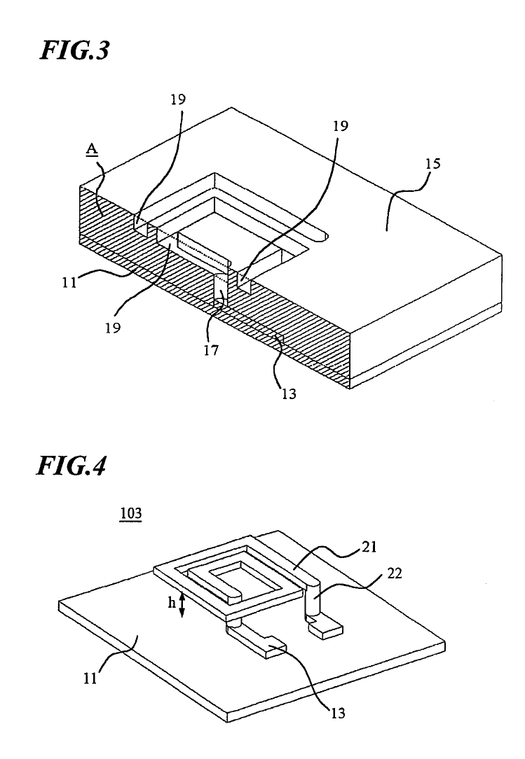

FIG. 3 is a perspective view of a three-dimensional sacrificial mold 15.

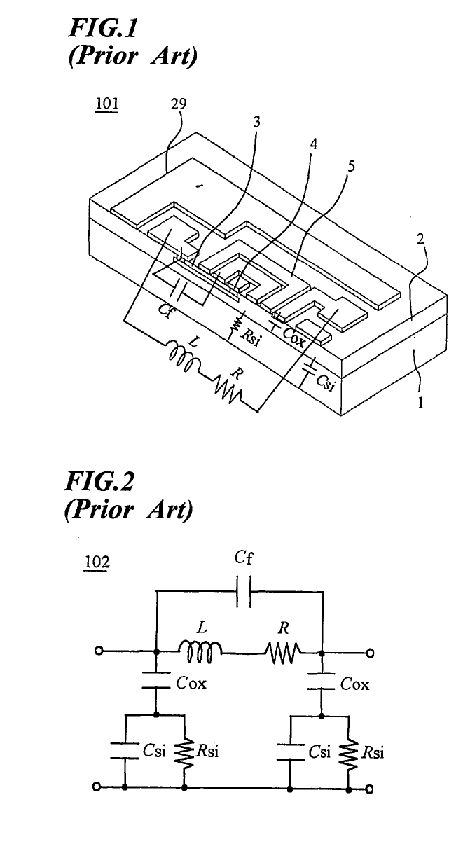

A substrate 11 can be made from semiconductor such as silicon, silicon germanium (SiGe) and gallium arsenide (GaAs), alumina, glass, quartz, other plastic materials. In other words, since process temperature is 120° C. or less, there is no limitation in the material of the substrate if the substrate is endurable at that temperature. Further, in case that the substrate 11 is a semiconductor substrate, it can include an integrated circuit. In case that there is an integrated circuit on the semiconductor substrate, either a bottom metal layer 13 or a lower portion of a first space 17 is electrically connected with the integrated circuit of the semiconductor substrate through an element such as the via 4 shown in FIG. 1. According to FIG. 3, the first space 17 is a vacant space formed in the three-dimensional sacrificial mold 15 at a predetermined height from a bottom of the three-dimensional sacrificial mold 15. The predetermined height is less than a height of the three-dimensional sacrificial mold 15. A second space is a vacant space from the height of the first space to a surface of the three-dimensional sacrificial mold. The first and second spaces necessarily have at least one portion communicating with each other. The three-dimensional sacrificial mold 15 can be made of a photosensitive or non-photosensitive-based polymer such as photoresist or polyimide, a glass-based material such as photosensitive glass or spin on glass, or a general plastic material or the like, each of which has the insulating property, can be coated in a thickness of a few ten micrometer, and can be selectively removed with respect to metal. Further, in order to form the first and second spaces 17 and 19 in the three-dimension, there can be used a method of two steps of ultra violet projection method described later and a general processing method such as a laser processing. The first and second spaces 17 and 19 are filled with a third metal layer through a method such as an electroplating, and the three-dimensional sacrificial mold 15 is removed, so that there is fabricated a three-dimensional spiral inductor 103 in which the third metal layer 21 having a spiral shape is supported by two first supporting bars 22 and is suspended at a height (h) of a few ten micrometer as shown in FIG. 4. For reference, if the first supporting bars 22 are directly connected with the integrated circuit on the substrate 11 through an element such as the via shown in FIG. 1, there is no needed the bottom metal layer 13 shown in FIG. 4.

Thus, by providing the structure suspended at a height, which cannot be realized by the conventional integration technology, an electromagnetic effect to the underlying integrated circuit due to the three-dimensional spiral inductor 103 is minimized to permit the integrated circuit to be formed below the spiral inductor 103, and a signal loss to the substrate 11 is minimized. Also, compared with the conventional inductor of which metal line realized by the conventional semiconductor technology has a thickness of 4 micrometers at most, the metal line of the three-dimensional inductor in accordance with the present invention is made of copper or gold having a low electrical resistance in a thickness of 10 micrometers or more, so as to have a low series resistance and a large current limitation. For reference, according to the experimental results performed by the inventors, an allowable current through a metal line of copper having a thickness of 20 micrometers and a width of 15 micrometers, respectively is approximately 180 mA, which corresponds to a value that is 100 times as high as a current density flowable through the copper line in the macro world. Hence, through the structure shown in FIG. 4 and the thickness aforementioned, it becomes possible to integrate the three-dimensional inductor having a high performance such a high Q-factor and a large current limitation with the conventional integrated circuit without additively using the substrate area.

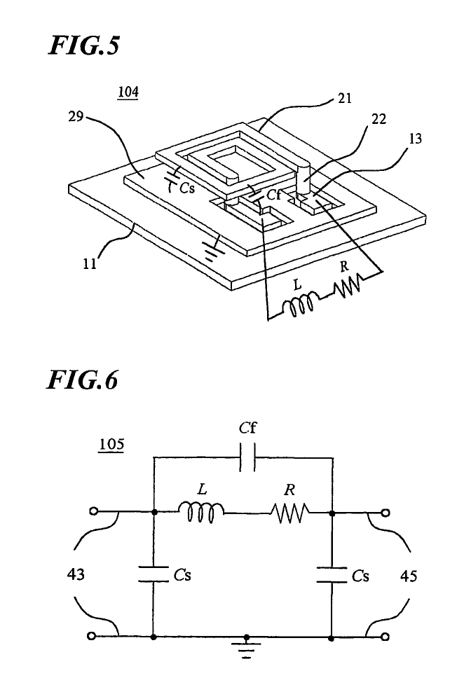

FIG. 5 shows a three-dimensional spiral inductor 104 in which a bottom ground metal layer 29 is provided below the three-dimensional spiral inductor 103 of FIG. 4. The bottom ground metal layer 29 is formed in the same manufacturing process as the bottom metal layer 13. Thus, by devising a structure in which a ground layer is provided below the suspended inductor, an electromagnetic wave generated from the inductor can not penetrate into the underlying substrate, so that a new three-dimensional inductor model 105 that is irrelevant to the substrate as shown in FIG. 6, is allowable. Comparing with the new three-dimensional inductor model of FIG. 6 with the conventional integrated inductor model of FIG. 2, the two models have a common point in that the third metal layer 21 that is the metal line for the spiral inductor has the series resistance (R) and the inductance component (L) within itself and the fringe capacitance (Cf) is generated between the third metal layer 21 and the underlying electrode. However, they have a difference in that a capacitance Cs having air as a medium exists instead of a capacitance Cox for an insulating layer connected between grounded portions of the first and second ports 43 and 45 and non-grounded portions of the first and second ports 43 and 45, and capacitance C_{Si} and resistance R_{Si} are removed from the structure of FIG. 2 due to the existence of the bottom ground layer 29. In other words, the structure of FIG. 5 enables a completion of a perfect physical model in which all parameters are decided only by a physical dimension of the inductor itself. Also, since the value of C_{Si} is a capacitance existing within a few ten micrometers, it has a value 10 times or more less than Cox existing within a few micrometers. This point functions to increase a usage frequency region of the inductor.

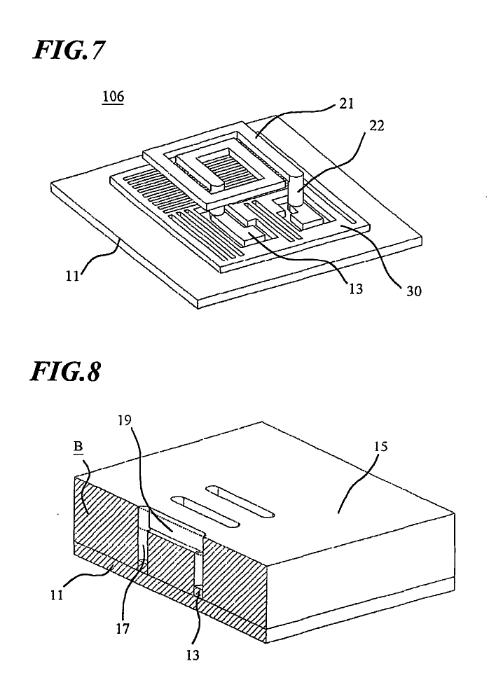

FIG. 7 shows a three-dimensional spiral inductor 106 having a patterned bottom ground metal layer 30. The patterned bottom ground metal layer 30 is to prevent an electromagnetic field generated from the inductor to induce an eddy current within the bottom ground metal layer 29 and to thus lower the performance of the inductor. The patterned ground metal layer having a predetermined pattern functions to finely cut a current flow that may be generated within the ground metal layer.

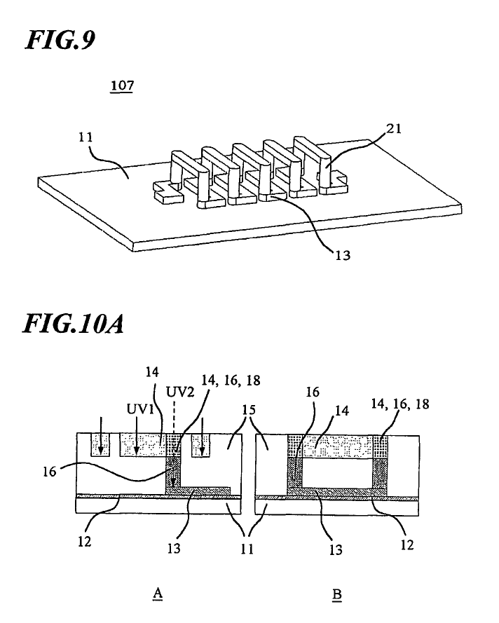

FIG. 8 is a perspective view of a three-dimensional sacrificial mold 15 used in the manufacturing of a solenoid inductor 107. Likewise that of FIG. 3, the three-dimensional sacrificial mold 15 is made in a three-dimensional shape and has a first space 17 and a second space 19. The first and second spaces 17 and 19 are filled with the third metal layer 21 through a method such as an electroplating or the like, and the three-dimensional sacrificial mold 15 is removed, so that the solenoid inductor 107 having a solenoid core height of a few ten micrometers is manufactured as shown in FIG. 9. Thus, by forming the core at a height that cannot be realized by the conventional integrated technology, there are generated effects in that a signal loss to the substrate is minimized and inductance is maximized.

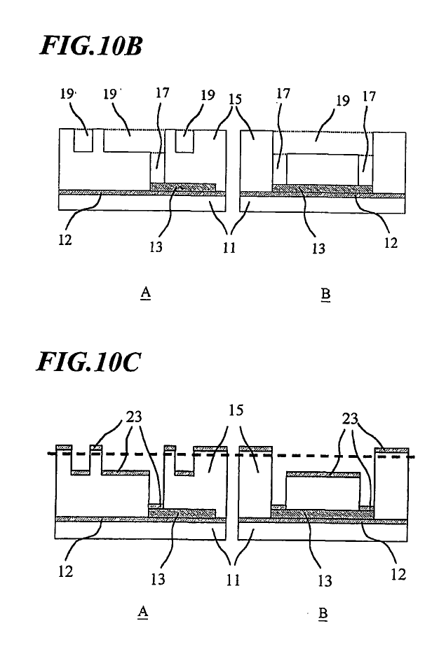

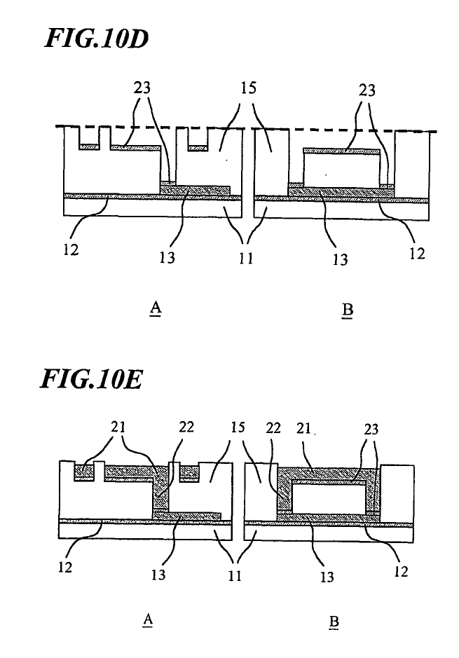

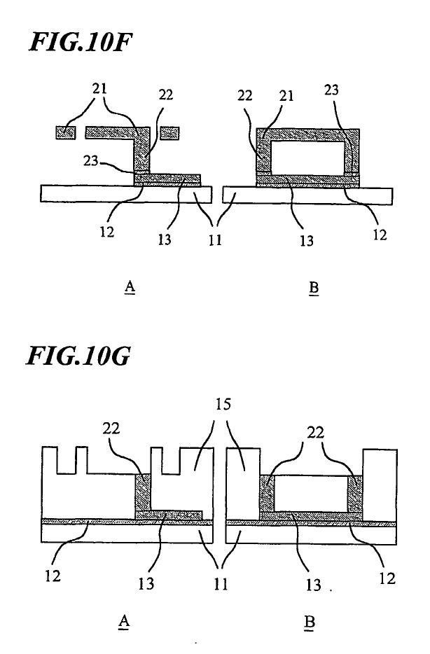

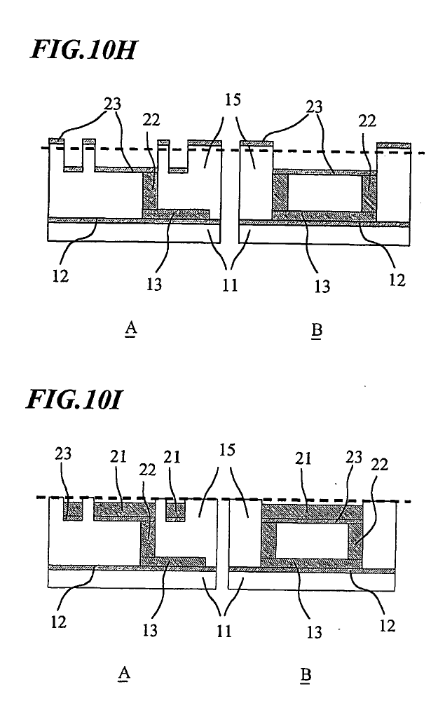

Next, FIG. 10a to FIG. 10f are sectional views for illustrating a process for manufacturing the three-dimensional spiral inductor 103 and the solenoid inductor 107 shown in FIG. 4 and FIG. 9, respectively in accordance with one embodiment of the present invention. For reference, since the three-dimensional spiral inductor 103 and the solenoid inductor 107 are the same in the manufacturing process, the section “A” shown in FIG. 3 and the section B shown in FIG. 8 are again shown in FIG. 10a to FIG. 10f.

To begin with, referring to FIG. 10a, a first metal layer 12 for an electroplating is formed on a substrate 11 provided with or not provided with an integrated circuit. The aforementioned substrates can be also used for the present embodiment. Most of metals having a good adhesive property to the substrate 11 can be used for the first metal layer 12. In this embodiment, titanium (Ti) or chromium (Cr) in a thickness of 0.02 micrometers, and copper or gold in a thickness of 0.2 micrometers are sequentially deposited without breaking a vacuum state. It is in advance described that all metal layers described hereinafter, i.e., bottom metal layer, and second to fourth metal layers are made of copper if the upper layer of the first metal layer 12 is copper, and are made of gold if the upper layer of the first metal layer is gold. Afterwards, if necessary, a bottom metal layer 13 is formed on the first metal layer 12 through a general photolithography and an electroplating. The bottom metal layer 13 can be also used as a bottom ground metal layer 29 or the like in a subsequent process. In this embodiment, the first metal layer is formed in a thickness of 10 micrometers from the same metal as in the upper layer of the first metal layer, out of copper or gold through the electroplating. Thereafter, a three-dimensional sacrificial mold 15 that is 40 micrometers or more thick is formed. In the embodiment, AZ9260 (Trademark name) made in US company of Clariant is used for the three-dimensional sacrificial mold 15 and is coated in a thickness of 80 micrometers. Afterwards, two steps of exposure processes are carried out. As shown in FIG. 10a, a first exposure step UV1 is carried out to a predetermined depth (30 micrometers in this embodiment) from an upper surface of the three-dimensional sacrificial mold 15 using a predetermined pattern to form a first exposure region 14, and a second exposure step UV2 is carried out to the bottom of the three-dimensional sacrificial mold using a different pattern from that used in the first exposure step UV1 to form a second exposure region 16. For reference, a third exposure region 18 is a twice exposed region, and corresponds to an intersection of the first exposure region 14 and the second exposure region 16. At this time, each of the first exposure regions 14 separated from each other has to contain at least one the third exposure region 18 that is overlapped with the second exposure region 16. In the present embodiment, the first exposure process UV1 is carried out for 60 seconds and the second exposure process UV2 is carried out for 300 seconds using an exposure unit having an ultraviolet power of 10 mW/cm², to form the first exposure region 14 having a thickness of 30 micrometers.

After the two steps of exposure processes are completed, the specimen is dipped in a development solution to develop the exposed portions. If the sacrificial mold is a positive photoresist, all exposed portions are removed to form vacant spaces in the three-dimensional sacrificial mold 15 as shown in FIG. 10b. The developing process is carried out using the solution named AZ340 (Trademark name) made in the US company of Clariant. At this time, the three-dimensional sacrificial mold 15 of the first exposure region 14 and the third exposure region 18 is removed to form a second space 19, and the three-dimensional sacrificial mold 15 of the second exposure region 16 is removed to form a first space 17, or the first space 17 and the second space 19. As described above, although one method for making the three-dimensional sacrificial mold 15 is described, a general method such as a laser processing can be also used. At this time, a height from the substrate to a lower portion of the first space 17 is 50 micrometers that corresponds to a value left after the height of the first space 17, 30 micrometers is extracted from the thickness of the three-dimensional sacrificial mold 15, 80 micrometers, and thereby the three-dimensional metal device is suspended by the height of 50 micrometers.

Thereafter, as shown in FIG. 10c, a second metal layer 23 is formed on the entire surface of the specimen. In the present embodiment, copper or gold that is the same as in the upper layer of the first metal layer is vacuum-deposited as the second metal layer 23 in a thickness of 0.05 micrometers. Afterwards, only the second metal layer 23 that is the uppermost layer of the three-dimensional sacrificial mold 15 is removed. This is because of the following reason. When the second metal layer 23 is vacuum-deposited, it is not deposited at side portions of the three-dimensional sacrificial mold 15 normal to the substrate 11, but is deposited only on a surface parallel to the substrate 11 as shown in FIG. 10c. However, if the second metal layer 23 is deposited at both sides of the three-dimensional sacrificial mold 15, the second metal layer that is the uppermost layer of the three-dimensional sacrificial mold 15, is electrically connected with the second metal layer below the first and second spaces 17 and 19, so that the uppermost layer of the three-dimensional sacrificial mold may be electroplated during a subsequent electroplating process. In order to prevent this phenomenon, only the second metal layer 23 that is the uppermost layer of the three-dimensional sacrificial mold 15 is removed. For the removal of the second metal layer 23 alone, there can be used various methods, for instance, a method in which only a surface of the specimen is dipped in an etchant of the second metal layer 23. In the present embodiment, a polishing process is particularly carried out. Dotted lines shown in FIGS. 10c and 10d are indicative of a depth to be polished. In other words, the polishing is carried out till the depth indicated by the dotted lines, to thereby remove the second metal layer 23 that is the uppermost layer of the three-dimensional sacrificial mold. FIG. 10d shows a section after the polishing is carried out till the dotted line.

After that, an electroplating or an electroless plating is performed, so that the first and second spaces 17 and 19 are filled with only the third metal layer 21 in the following order as shown in FIG. 10e. If the electroplating starts from a state of FIG. 10d, the electroplating is generated only at the first space 17 until the first space 17 is filled with the third metal layer 21 to form the first supporting bar 22. After the first space 17 is filled with the third metal layer 21, the third metal layer 21 becomes in contact with the second metal layer 23 laid below the second space 19, so that the electroplating starts on an upper surface of the second metal layer 23 placed at a lower portion of the second space 19 and thereby the second space 19 is also filled with the third metal layer 21. In other words, the first and second spaces 17 and 19 are successively filled with the third metal layer 21 by once electroplating process, so that the first supporting bar 22 forms one body with the overlying third metal layer 21 without disconnecting with the third metal layer 21. This is a structural characteristic of the present embodiment, and is advantageous in terms of mechanical rigidity and series resistance. For reference, it is requested that the first spaces separated from each other necessarily contain at least one portion communicating with the second space within the respective first spaces, and the second spaces separated from each other necessarily contain at least one portion communicating with the first space within the respective second spaces, thereby capable of forming the first supporting bar 22 and the third metal layer 21 made in one body.

Although the second metal layer 23 is arranged at both sides of the three-dimensional sacrificial mold 15, the first and second spaces 17 and 19 are filled with the third metal layer 21 alone. At this time, although the third metal layer 21 is protruded upward from the three-dimensional sacrificial mold 15, the protruded portions can be removed by a polishing process. In the present embodiment, the third metal layer 21 is formed of copper or gold that is the same material as in the second metal layer 23. It is requested that the third metal layer 21 filled in the second space 19 be 10 micrometers or more thick.

Next, the three-dimensional sacrificial mold 15 is removed by a removal solution of the three-dimensional sacrificial mold, such as organic solvents (acetone) or the like. When the three-dimensional spiral inductor and the solenoid inductor are viewed after the three-dimensional sacrificial mold is removed, the three-dimensional metal devices manufactured on the substrate are electrically connected with each other through the first metal layer 12. So, for the electrical isolation between the devices, a step of removing a part of the first metal layer 12 is performed. If the upper metal of the first metal layer consisting of the two metal layers is copper, the specimen is dipped in a copper etchant, and if the upper metal layer of the first metal layer is gold, the specimen is dipped in a gold etchant, thereby removing the bottom metal layer 13 or the upper metal of the first metal layer 12 of the entire regions except for the portion positioned below the first supporting bar 22 if the bottom metal layer 13 does not exist. At this time, since the third metal layer 21 including the first supporting bar 22 is the same metal as the upper metal of the first metal layer 12, a surface thereof is etched, but since an etched thickness of the third metal layer 21 is very small compared with the thickness of the structure, it can be ignored. However, since the second metal layer is thin in thickness thereof, the second metal layer 23 exposed to the outside in FIG. 10e, e.g., the portion positioned below the first space 19, is removed together. Next, if the lower metal of the first metal layer 12 is titanium, the specimen is dipped in a titanium etchant, and if the lower metal is chromium, the specimen is dipped in a chromium etchant, thereby removing the bottom metal layer 13 or the lower metal of the first metal layer 12 of the entire regions except for the portion positioned below the first metal layer 12 if the bottom metal layer 13 does not exist. Through the above processes, there are manufactured the three-dimensional spiral inductor 103 and the solenoid inductor 107 which are suspended with the sectional structure shown in FIG. 10f.

FIGS. 10g-10j are sectional view schematically showing a manufacturing process of a three-dimensional spiral inductor 103 and a solenoid inductor 107 in accordance with another embodiment of the present invention. The manufacturing process in accordance with the present embodiment includes the steps of forming the three-dimensional sacrificial mold 15 including the first space 17 and the second space 19 shown in FIG. 10a and FIG. 10b. Next, as shown in FIG. 10g, the first space 17 is filled with the third metal layer 21 through an electroplating or electroless plating, so that the first supporting bar 22 is formed. There is no need that the height of the first supporting bar 22 exactly corresponds to that of the first space, i.e., the first supporting bar may be higher or lower than the first space, which does not affect on a subsequent process. Thereafter, as shown in FIG. 10h, a second metal layer 23 is formed on the uppermost surface of the three-dimensional sacrificial mold 15, at a lower portion of the second space 19, and on the first supporting bar 22 like wise the previous embodiment. Afterwards, a polishing process is performed, in which dotted lines shown in FIGS. 10h and 10i are indicative of a depth until which the polishing process is being performed. In other words, the polishing step is performed until the depth indicated by the dotted line, to thereby remove only the second metal layer 23 arranged on the uppermost surface of the three-dimensional sacrificial mold. The reason is the same as that described in the previous embodiment. FIG. 10i shows a status in which the polishing has been performed until the dotted line and then an electroplating or electroless plating is performed at a metal thickness of 10 micrometers or more, so that the second space 19 is filled with the third metal layer 21.

Thereafter, likewise the previous embodiment, the three-dimensional sacrificial mold 15 is removed using acetone or the like, and then a part of the first metal layer is removed for an electrical isolation between devices, so that there are manufactured a three-dimensional spiral inductor 103 and a solenoid inductor 107 which are suspended with the sectional structure shown in FIG. 10j.

Selectively, in order to decrease the series resistance and increase the Q-factor by thickening the metal line of the three-dimensional metal devices having the structures shown in FIGS. 10f and 10j interconnection, or smoothing the surface of the metal line, an electroless plating of copper, gold or the like may be further performed or a little etching process in a gold etchant may be further performed. The electroless plating can be performed with respect to any region of an exposed surface of a metal. To this end, if the electroless plating is performed in the status of FIGS. 10f and 10j, gold film or copper film is plated around the bottom metal layer 13, the first supporting bar 22, and the third metal layer, so that they thicken. Also, if their surfaces are rough, since the rough surface increases the series resistance, the layers are slightly etched in a proper etchant in order to smooth the surfaces of them.

All the manufacturing procedures described in the above two embodiments are performed below a temperature of 120° C. To this end, although an integrated circuit is included in the substrate, there is an advantage in that the processes can be performed without affecting at all on the underlying integrated circuit.

The aforementioned two embodiments show and describe the methods capable of manufacturing various three-dimensional metal devices. Hereinafter, there are described various three-dimensional metal devices other than the aforementioned suspended three-dimensional spiral inductor and the like.

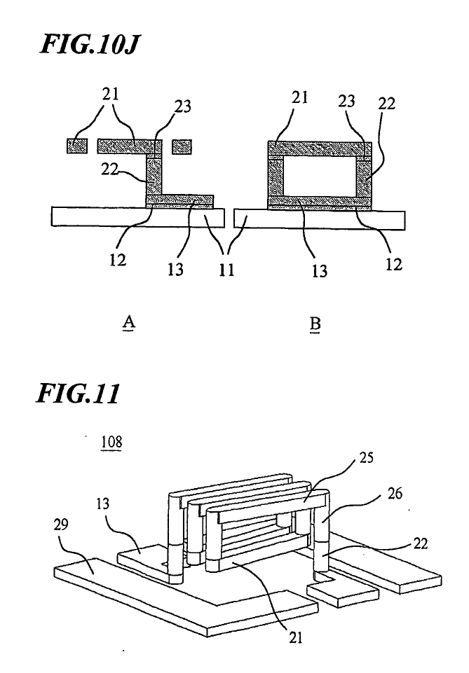

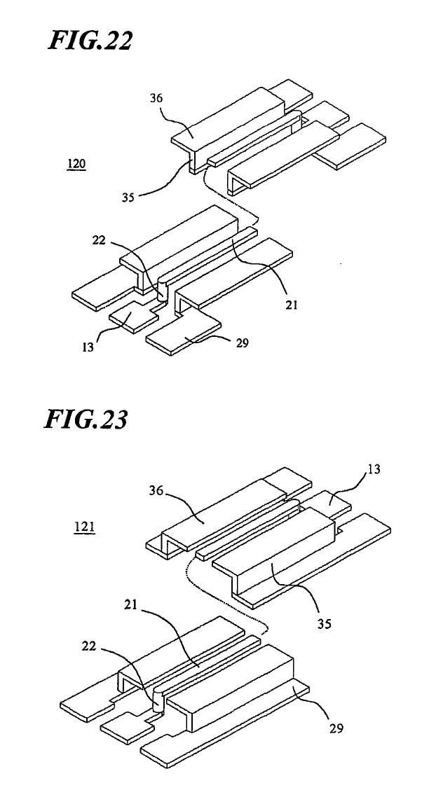

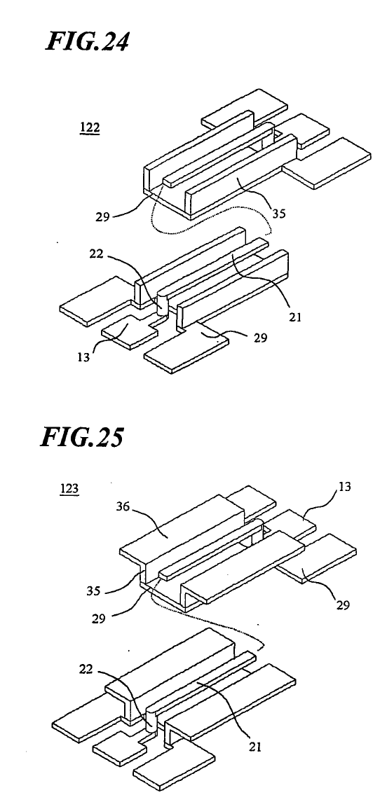

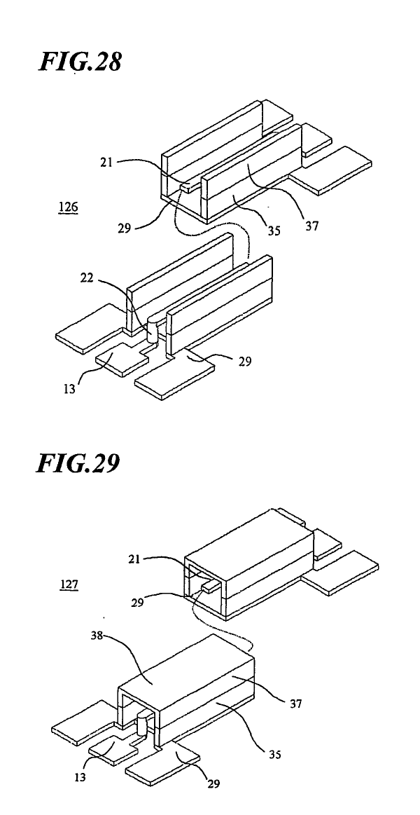

FIG. 11 is a perspective view of a three-dimensional suspended solenoid inductor 108 in accordance with another embodiment of the invention. For reference, the substrate is intentionally omitted in FIGS. 11-31. The structure shown in FIG. 11 can be manufactured by repeatedly performing a part of the manufacturing steps of the first embodiment. In other words, by performing the steps of from FIG. 10a to FIG. 10e, the first supporting bar 22 and the third metal layer 21 are formed in one body, and then by performing the steps of from FIG. 10a in which the three-dimensional sacrificial mold is not removed and a further three-dimensional sacrificial mold layer is formed on the previous formed three-dimensional sacrificial mold, to FIG. 10f, a suspended three dimensional solenoid inductor 108 in which a second supporting bar 26 and a fourth metal layer 27 are formed is manufactured as shown in FIG. 11. For reference, this structure may be manufactured by performing a part of the manufacturing steps of the second embodiment. Thus, the aforementioned two embodiments related with the manufacturing processes can be applied to the manufacturing of all three-dimensional metal devices.

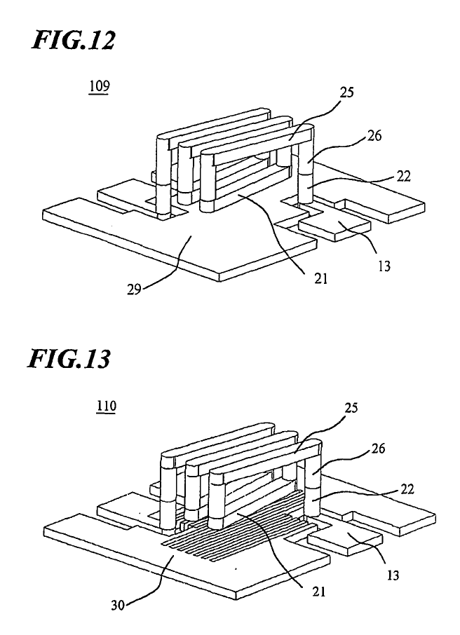

Next, FIG. 12 shows a suspended three-dimensional solenoid inductor 109 with a bottom ground metal layer 29 installed therebelow. Like the structure of FIG. 5, since the suspended three-dimensional solenoid inductor 109 has the bottom ground metal layer 29 installed therebelow, the influence of the inductor upon the substrate is completely excluded, so that it becomes possible to use a new three-dimensional inductor model 105 having nothing to do with the substrate.

Also, FIG. 13 shows a structure of a suspended three-dimensional solenoid inductor 110 with a patterned bottom ground metal layer 30. This structure has the same advantage as that described in FIG. 7.

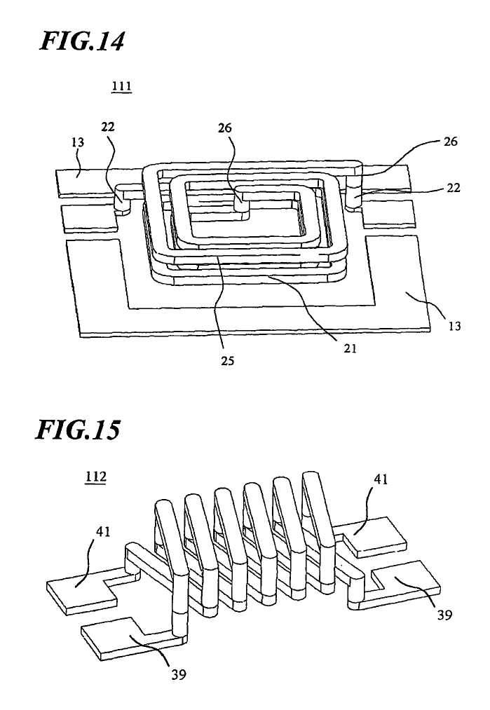

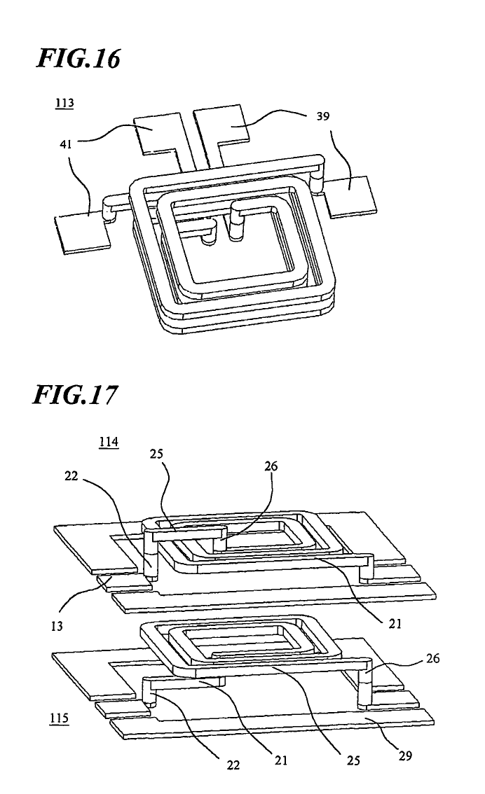

FIG. 14 shows a stacked three-dimensional spiral inductor 111 in which two spiral inductors are vertically stacked, are serially connected with each other, and a lower spiral inductor is also suspended. Like the previous description, if necessary, the bottom ground metal layer 29 or the patterned bottom ground metal layer 30 can be further formed in the stacked three-dimensional spiral inductor 111. Like the manufacturing process of the suspended three-dimensional solenoid inductor 108 shown in FIG. 11, the suspended three-dimensional spiral inductor 111 can be manufactured by repeating once more a part of the manufacturing steps of the first embodiment or the second embodiment. The stacked type spiral inductor structure has an advantage in that a large inductance can be obtained compared with an area occupied by the inductor on the substrate. In addition to the advantage, by floating the stacked type spiral inductor over the substrate, the structure of FIG. 13 is advanced to further have the advantages of the suspended three-dimensional metal devices described above. If the part of the manufacturing steps of the first embodiment or the second embodiment is performed not once more but two times or more, a three-dimensional spiral inductor in which three layers or more are stacked can be manufactured. These methods can be applied to all embodiments including the stacked three-dimensional spiral inductor, so that various metal devices having a three-dimensional structure can be manufactured. Also, by simply modifying the solenoid inductors structures proposed in FIG. 9, and FIGS. 11-13, e.g., not connecting the solenoid turns in one strand but alternating a fist turn 39 and a secondary turn 41 as shown in FIG. 15, or winding the secondary turn 41 every first turn 39, a suspended three-dimensional solenoid transformer 112 having a low substrate loss, a low insertion loss, a wide passing frequency band and a high coupling coefficient can be manufactured. Likewise, by not serially connecting the two layered three-dimensional spiral inductors in the stacked three-dimensional spiral inductor structure of FIG. 14 but separating them from each other to make the first turns 39 and the secondary turns 41, and connecting the separated first and second turns 39 and 41 using respective connection lines extending to the outside, a suspended three-dimensional spiral transformer 113 having a low substrate loss, a low insertion loss, a wide passing frequency band and a high coupling coefficient can be manufactured. (Refer to FIG. 16) FIG. 17 shows three-dimensional spiral inductors 114 and 115 having two kinds of different structured lead wires. The manufacturing methods of the three-dimensional spiral inductors 114 and 115 are the same with that of the suspended three-dimensional solenoid inductor 108 shown in FIG. 11. The three-dimensional spiral inductor 114 having an upward suspended lead wire and the three-dimensional spiral inductor 115 having a downward suspended lead wire have a common point in that the lead wires connecting the inside of the inductor with the outside of the inductor are suspended. To this end, in any structure needing the lead wire, a signal loss due to the lead wire can be prevented. Also, in the event of the three-dimensional spiral inductor 15 having the downward suspended lead wire, the spiral inductor portion is further highly suspended from the substrate.

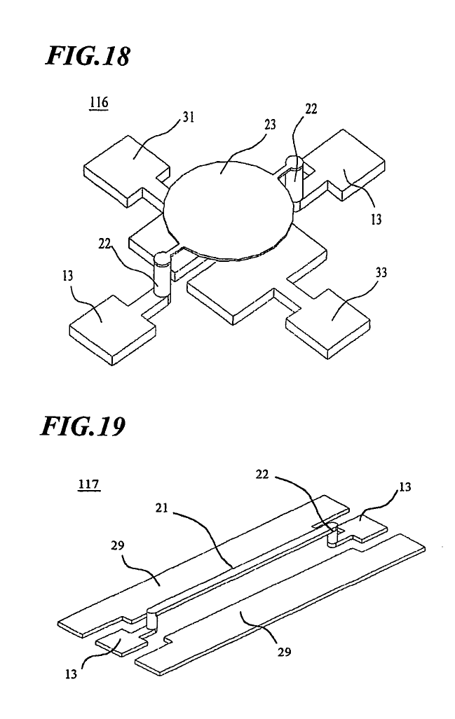

The above embodiments describe only the variety of inductors among the suspended three-dimensional metal devices. Next, FIG. 18 is a perspective view showing a three-dimensional shape of a three-dimensional micromirror 116 in accordance with the present invention.

This structure can be completed without the third metal layer 21 by excluding the electroplating process shown in FIG. 10i among the manufacturing processes described in the second embodiment. At this time, the second metal layer 23 used as the mirror is formed thicker than the first metal layer 21 considering that the second metal layer 23 is partially etched during the etch process of the first metal layer 21, or the second metal layer 23 is made of different material from the first metal layer 21 such that the second metal layer is not etched by an etchant used in etching the first metal layer 21. The manufactured three-dimensional micromirror 116 is driven by an electrostatic force, and thereby the micro face made of the second metal layer 23 is warped by a predetermined angle. In other words, if a voltage is applied between at least one of electrode plates existing in a lower portion of the mirror face, such as a first signal electrode 31 or a second signal electrode 33, and a bottom metal layer 13 electrically isolated from the electrode plate, electrostatic force is generated by a charge induced between the two plates, so that the two plates are pulled to each other.

Since this three-dimensional micromirror 116 can manipulate a light path using an electrical signal, it used in an optical switch that is very important device in the optical telecommunications system.

FIGS. 19-29 are perspective views showing three-dimensional shapes of various structures of three-dimensional transmission lines in accordance with the present invention.

For reference, each of the three-dimensional transmission lines respectively shown in FIGS. 19-29 is divided into two pieces in order to show sections thereof, and the dotted lines represent that the two pieces are connected with each other. The transmission lines are main devices for transmission of ultrahigh frequency signals. However, since the conventional transmission lines manufactured by the conventional integration technology are arranged very adjacently to the substrate, it is difficult to use the min the silicon substrate generally having a high signal loss to the substrate. On the contrary, as shown in FIGS. 19-29, the signal lines formed from the third metal layer 21 are suspended at a few ten micrometers from the substrate, which enables to remarkably decrease the signal loss to the substrate, so that the transmission lines having a very good insertion loss characteristic can be obtained even on the silicon substrate that is cheap in price and widely used. Reviewing the transmission lines 117-127 in detail shown in FIGS. 19-29, it is well known that all of the signal lines having the same structure formed from the third metal layer 21, e.g., suspended at a few ten micrometers from the substrate. However, they have a difference in the ground structure thereof with the surroundings. The characteristics of the signal lines formed from the third metal line 21 are varied with the ground structures. The ground structure includes a bottom ground metal layer 29, a first ground wall 35, a first ground wing 36, a second ground wall 37 and a second ground wing. The first ground wall 35 is formed by coupling a first supporting bar 22 with the third metal layer 21 in the same shape. The first ground wing 36 is formed from the third metal layer 21 having a certain shape. The second ground wall 37 is formed by coupling a second supporting bar 26 with a fourth metal layer 25 in the same shape. The second ground wing 38 is formed from the fourth metal layer having a certain shape.

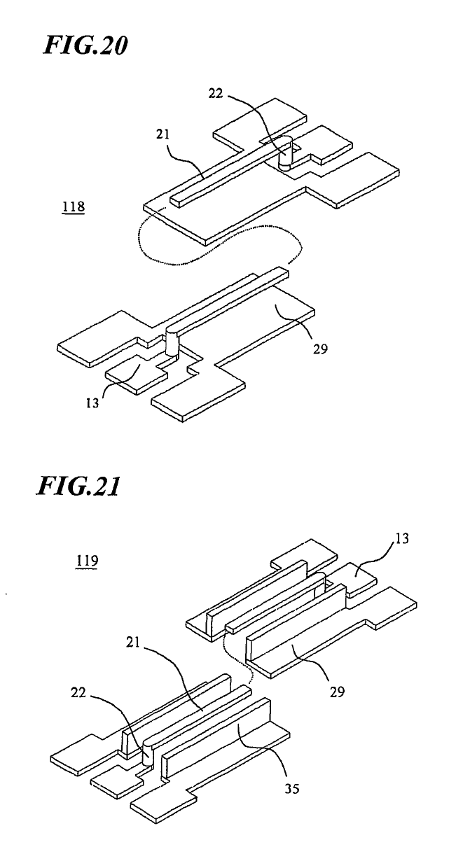

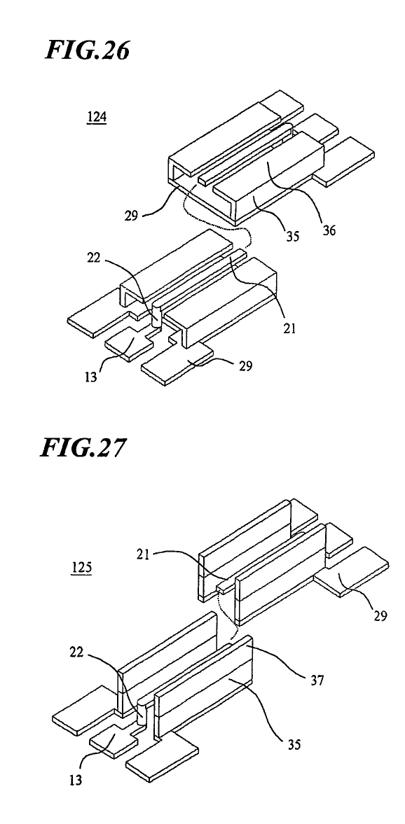

For reference, FIG. 20 shows a structure in which a microstrip line having air medium is realized over the substrate, FIG. 23 shows a structure in which a coplanar waveguide is suspended above the substrate, and FIG. 26 shows a new type of coplanar microstrip line structure in which the structure of FIG. 20 and the structure of FIG. 23 are coupled to each other. Further, FIG. 29 shows a structure in which a coaxial cable having air medium is suspended above the substrate. In the structure of FIG. 29, since the signal line is completely surrounded by the ground plate, signal interference to other portions is remarkably obstructed. Among these structures, which ground structure is being used is determined considering the insertion loss that is necessary for real use, isolation characteristic or the like. The present embodiment devises and provides the three-dimensional transmission lines 117-127 that could not be used since they could not be realized by the conventional technology.

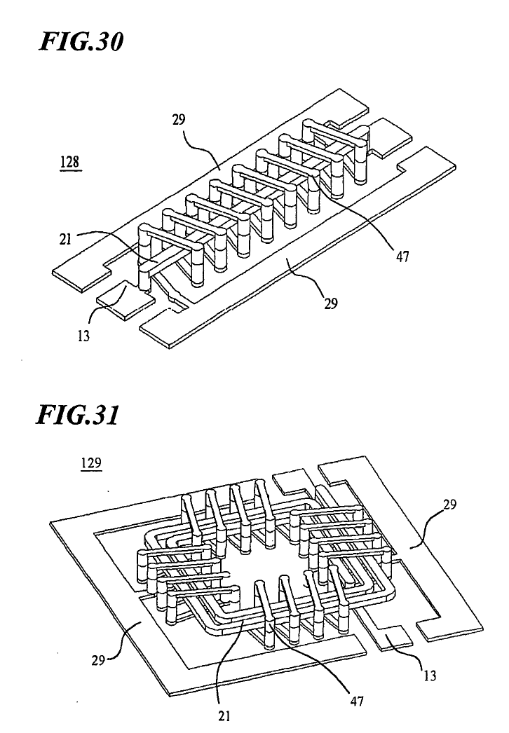

While FIGS. 19-29 show the ground structures having a plate shape, FIG. 30 shows a three-dimensional transmission line 128 having a solenoid shape of ground line 47, and FIG. 31 shows a three-dimensional spiral inductor 129 having the solenoid shape of ground line 47. The ground lines 47 shown in FIGS. 30 and 31 have a peculiar structure that provides a surrounding of the three-dimensional metal device with a proper ground and decreases a loss due to the eddy current flowing through the ground metal.

The variety of three-dimensional metal devices manufactured according to all the embodiments of the invention have an element suspended above the substrate commonly, which may cause a partial lack in the mechanical stability. However, according to an experiment, mechanical strength (or stiffness) of copper used as the metal line is very superior. Concretely, if the metal line is 20 micrometers or more in width and 20 micrometers or more in thickness, it is very strong against a mechanical impact. In addition, the metal devices in which all processes are ended and an element thereof is suspended can be encapsulated using an encapsulating material, which induces mechanical and electrical stability of the devices and makes easy the packaging thereof. A prior use example of the encapsulating material is melted wax used for fixing the interval between solenoid coils in the radio. Nowadays, the encapsulating material is frequently used in the packaging of the semiconductor devices. It is disclosed that all encapsulating materials including a wax-based encapsulating material such as paraffin, silicone for semiconductor packaging having insulation and sealing properties, etc., can be used in the present invention. For reference, there is a report in that an increase in the signal loss generated when these encapsulating materials are provided is within 10%.

While the present invention has been described in detail, it should be understood that various changes, substitutions and alterations can be made hereto without departing from the spirit and scope of the invention as defined by the appended claims.

### INDUSTRIAL APPLICABILITY

As described previously, according to the present invention provides three-dimensional metal devices, in which various passive electrical devices for radio telecommunications and optical telecommunications, such as spiral inductor, solenoid inductor, spiral transformer, solenoid transformer, micromirror, transmission line and the like, are made from metal and are suspended above a semiconductor substrate, to decrease an area occupied by the devices remarkably and thus increase the integrity of the circuit, and further to remarkably reduce an influence of the devices upon the underlying integrated circuit and signal loss to the substrate, thus allow the devices to have a superior performance, and thereby make it possible to manufacture the device models independently from the substrate. Furthermore, the invention allows metal lines of the three-dimensional metal devices to have a thickness of 10 micrometers or more, so that the metal lines come to have a small series resistance and a high current limitation.

Moreover, the manufacturing methods provided together with the structures of the thee-dimensional metal devices mainly use a general semiconductor process, an electroplating process, a polishing process include and the like. To this end, the manufacturing methods are easy and elaborate. If the processes are repeatedly applied, complicated and a variety of three-dimensional metal devices can be formed. Also, since the metal devices does not influence an integrated circuit manufactured previously on the substrate at all, the methods can be exchangeable with the conventional semiconductor integrated circuit processes.

1. A method for manufacturing a three-dimensional metallic device highly suspended above a substrate, the method comprising the steps of:
(a) preparing the substrate;
(b) forming a three-dimensional sacrificial mold in a three-dimensional structure having a first space extending from a bottom of the three-dimensional sacrificial mold to an upper portion thereof, and a second space connected with the first space and spaced apart from the bottom of the three-dimensional sacrificial mold;
(c) filling the first and second spaces with a third metallic layer; and
(d) removing the three-dimensional sacrificial mold.

2. The method of claim 1, after the step of (c), further comprising the steps of: again performing the step of (b) with respect to the three-dimensional sacrificial mold and an upper surface of the third metallic layer, and filling a resultant structure with a fourth metallic layer; and removing all the three-dimensional sacrificial mold.

3. The method of claim 1 or 2, wherein the step of forming the three-dimensional sacrificial mold comprises the steps of:
coating the three-dimensional sacrificial mold layer;
exposing the coated three-dimensional sacrificial mold layer to a predetermined depth using a first exposure pattern, to form a first exposure region;
full-exposing the three-dimensional sacrificial mold layer to the bottom thereof using a second exposure pattern overlapped with the first exposure pattern, to form a second exposure region and a third exposure region which is overlap-exposed with the second exposure region; and
removing all the exposed regions within the three-dimensional sacrificial mold layer using a single development process, to form the second space at a space of the first and third exposure regions and form the first space at a space of the second exposure region, or vice verse.

4. The method of claim 1 or 2, wherein the first space is a vacant space formed within the three-dimensional sacrificial mold at a predetermined height from the bottom of the three-dimensional sacrificial mold, the first space being positioned lower than the three-dimensional sacrificial mold, and the second space is a vacant space formed within the three-dimensional sacrificial mold from the height of the first space to a surface of the three-dimensional sacrificial mold, the first space and the second space essentially having at least one portion communicating with each other.

5. The method of claim 3, wherein each of the first exposure regions separated from each other comprises at least one the third exposure region overlapped with the second exposure region within the first exposure region.

6. The method of claim 1 or 2, wherein the sacrificial mold is an insulating material that can be easily coated in a thickness of a few ten micrometer and be selectively removed with respect to metal.

7. The method of claim 6, wherein the sacrificial mold is made of one selected from a group consisting of a photosensitive or non-photosensitive polymer-based material such as photoresist or polyimide, a glass-based material including a photosensitive glass or spin-on glass, and a general plastic material.

8. The method of claim 1 or 2, the second space is spaced apart from the bottom of the sacrificial mold in a horizontal direction, and the first space is 30 micrometers or more high such that a metal layer to be formed in the second space is suspended at a height of 30 micrometers or more.

9. The method of claim 1 or 2, wherein the substrate is a material endurable at a temperature of 120° C., and is one selected from a group consisting of semiconductor material, alumina, glass, quartz and plastic each of which can includes an integrated circuit thereon.

10. The method of claim 1 or 2, wherein the step of preparing the substrate further comprises a step of forming a first metal layer on the substrate, or comprises the steps of: forming the first metal layer on the substrate; and forming a bottom metal layer on the first metal layer.

11. The method of claim 10, wherein the step of filling the first and second spaces with the third metal layer or the fourth metal layer, comprises the steps of:
forming the second metal layer at the uppermost portion of the three-dimensional sacrificial mold, below the first space, and below the second space;
removing a portion disposed at the uppermost portion of the three-dimensional sacrificial mold in the second metal layer; and
filling the first and second spaces with the third metal layer or the fourth metal layer through an electroplating or an electroless plating.

12. The method of claim 10, wherein the step of filling the first and second spaces with the third metal layer or the fourth metal layer, comprises the steps of:
filing the first space with the third metal layer or the fourth metal layer through the electroplating or the electroless plating;
forming the second metal layer at the uppermost portion of the three-dimensional sacrificial mold, below the second space, and the upper portion of the third metal layer or the fourth metal layer;
removing the uppermost portion of the three-dimensional sacrificial mold in the second metal layer; and
forming the third metal layer or the fourth metal layer on the second metal layer through the electroplating or the electroless plating.

13. The method of claim 11, wherein the step of removing the portion disposed at the uppermost portion of the three-dimensional sacrificial mold in the second metal layer, is performed by a polishing process.

14. The method of claim 12, wherein the step of removing the portion disposed at the uppermost portion of the three-dimensional sacrificial mold in the second metal layer, is performed by a polishing process.

15. The method of claim 11, wherein the step of filling the first space with the third metal layer or the fourth metal layer, further comprises a step of performing a polishing process for removing the third metal layer or the fourth metal layer protruded to an upper portion of the second space.

16. The method of claim 12, wherein the step of filling the first space with the third metal layer or the fourth metal layer, further comprises a step of performing a polishing process for removing the third metal layer or the fourth metal layer protruded to an upper portion of the second space.

17. The method of claim 10, further comprising a step of removing a part of the metal layer for an electrical isolation between devices.

18. The method of claim 1 or 2, further comprising a step of performing an electroless plating using copper or gold, or slightly etching the metal line of the three-dimensional metal device so as to thicken or smooth the metal line of the three-dimensional metal device, thereby enhancing a Q-factor.

19. The method of claim 1 or 2, further comprising a step of covering the three-dimensional metal device of which part is suspended, with a wax-based material such as paraffin or a packaging sealant having insulation and sealing property, such as silicone, to thereby stabilize the device electrically and mechanically and facilitate the packaging.

20. The method of claim 11, wherein the first metal layer is formed by sequentially depositing a titanium film or a chromium film in a thickness within 0.1 micrometer, and a copper film or a gold film in a thickness within 1 micrometer without breaking a vacuum state, the second metal layer, the third metal layer and the fourth metal layer are all made of copper if a material on the first metal layer is copper, the bottom metal layer, the second metal layer, the third metal layer and the fourth metal layer are all made of gold if a material on the first metal layer is gold, the bottom metal layer, the second metal layer is vacuum-deposited in a thickness within 0.1 micrometer, and the third and fourth metal layers are formed in a thickness of approximately 10 micrometer or more.

21. The method of claim 12, wherein the first metal layer is formed by sequentially depositing a titanium film or a chromium film in a thickness within 0.1 micrometer, and a copper film or a gold film in a thickness within 1 micrometer without breaking a vacuum state, the bottom metal layer, the second metal layer, the third metal layer and the fourth metal layer are all made of copper if a material on the first metal layer is copper, the bottom metal layer, the second metal layer, the third metal layer and the fourth metal layer are all made of gold if the material on the first metal layer is gold, the second metal layer is vacuum-deposited in a thickness within 0.1 micrometer, and the third and fourth metal layers are formed in a thickness of approximately 10 micrometer or more.

22. A three-dimensional spiral inductor comprising:
a third metal layer suspended in a spiral shape;
two first supporting bars connected with a underlying substrate or a bottom metal layer vertically from an inner end and an outer end of the spiral shaped third metal layer, for supporting the third metal layer; and
any one among the substrate below the first supporting bars, the substrate and the bottom metal layer on the substrate, the substrate and a bottom ground metal layer on the substrate, the substrate and a patterned bottom ground metal layer on the substrate, the substrate, the bottom metal layer on the substrate and the bottom ground metal layer on the substrate, and the substrate, the bottom metal layer on the substrate and the patterned bottom ground metal layer on the substrate.

23. The three-dimensional spiral inductor of claim 22, further comprising a ground wire in a solenoid shape around the three-dimensional inductor.

24. A solenoid inductor comprising:
at least one third metal layer suspended in a bar shape;
two first supporting bars respectively connected with opposite ends of two adjacent bottom metal layers having the bar shape vertically from both ends of the third metal layer, for supporting the bar-shaped third metal layer;
the bottom metal layers disposed below the first supporting bar and having the bar shape; and
a substrate disposed below the bottom metal layer.

25. A three-dimensional solenoid inductor comprising:
at least one fourth metal layer suspended in a bar shape;
two second supporting bars connected with opposite ends of two adjacent third metal layers suspended in a bar shape vertically from both ends of the fourth metal layer, for supporting the fourth metal layer;
at least one third metal layer disposed below the second supporting bar and having the bar shape;
two first supporting bars vertically connected with a underlying substrate, a bottom metal layer or an integrated circuit on the substrate from both ends of the suspended solenoid inductor including the fourth metal layer, the second supporting bars, and the bar-shaped third metal layer, for supporting the suspended solenoid inductor; and
any one among the substrate below the first supporting bar, the substrate and the bottom metal layer on the substrate, the substrate and a bottom ground metal layer on the substrate, the substrate and a patterned bottom ground metal layer on the substrate, the substrate, the bottom metal layer on the substrate and the bottom ground metal layer on the substrate, and the substrate, the bottom metal layer on the substrate and the patterned bottom ground metal layer on the substrate.

26. A stack type three-dimensional spiral inductor comprising:
a fourth metal layer suspended in a spiral shape;
two second supporting bars connected with one end of an underlying third metal layer suspended in the spiral shape vertically from one end of the spiral-shaped fourth metal layer, connected with an underlying first supporting bar vertically from the other end of the fourth metal layer;
the third metal layer disposed below the second supporting bars and suspended in the spiral shape;
two first supporting bars vertically connected with a underlying substrate, a bottom metal layer or an integrated circuit disposed on the substrate from one end that is not connected with the second supporting bar and a lower portion of the second supporting bar that is not connected with the third metal layer, for supporting the two-layered spiral inductors connected in series; and
any one among the substrate below the first supporting bar, the substrate and the bottom metal layer on the substrate, the substrate and a bottom ground metal layer on the substrate, the substrate and a patterned bottom ground metal layer on the substrate, the substrate, the bottom metal layer on the substrate and the bottom ground metal layer on the substrate, and the substrate, the bottom metal layer on the substrate and the patterned bottom ground metal layer on the substrate.

27. A three-dimensional spiral inductor having an upward suspended lead wire, comprising:
a fourth metal layer suspended in a bar shape;
two second supporting bars connected with one end of an underlying third metal layer suspended in a spiral shape vertically from one end of the bar-shaped fourth metal layer, connected with an underlying first supporting bar vertically from the other end of the fourth metal layer;
the third metal layer disposed below the second supporting bars and suspended in the spiral shape;
two first supporting bars connected with a underlying substrate, a bottom metal layer or an integrated circuit disposed on the substrate vertically from one end that is not connected with the second supporting bar and a lower portion of the second supporting bar that is not connected with the third metal layer, for supporting the spiral inductor having the upward suspended lead wire; and
any one among the substrate below the first supporting bar, the substrate and the bottom metal layer on the substrate, the substrate and a bottom ground metal layer on the substrate, the substrate and a patterned bottom ground metal layer on the substrate, the substrate, the bottom metal layer on the substrate and the bottom ground metal layer on the substrate, and the substrate, the bottom metal layer on the substrate and the patterned bottom ground metal layer on the substrate.

28. A three-dimensional spiral inductor having a downward suspended lead wire, comprising:
a fourth metal layer suspended in a spiral shape;
two second supporting bars connected with one end of an underlying third metal layer suspended in a bar shape vertically from one end of the spiral-shaped fourth metal layer, connected with an underlying first supporting bar vertically from the other end of the fourth metal layer;
the third metal layer disposed below the second supporting bars and suspended in the bar shape;
two first supporting bars connected with a underlying substrate, a bottom metal layer or an integrated circuit disposed on the substrate vertically from one end that is not connected with the second supporting bar and a lower portion of the second supporting bar that is not connected with the third metal layer, for supporting the spiral inductor having the downward suspended lead wire; and
any one among the substrate below the first supporting bar, the substrate and the bottom metal layer on the substrate, the substrate and a bottom ground metal layer on the substrate, the substrate and a patterned bottom ground metal layer on the substrate, the substrate, the bottom metal layer on the substrate and the bottom ground metal layer on the substrate, and the substrate, the bottom metal layer on the substrate and the patterned bottom ground metal layer on the substrate.

29. A suspended three-dimensional solenoid transformer comprising two suspended three-dimensional solenoid inductors, the suspended three-dimensional solenoid inductor comprising:
at least one fourth metal layer suspended in a bar shape;
two second supporting bars connected with opposite ends of two adjacent third metal layers suspended in a bar shape from both ends of the fourth metal layer, for supporting the fourth metal layer;
at least one third metal layer disposed below the second supporting bar and having the bar shape;
two first supporting bars vertically connected with a underlying substrate, a bottom metal layer or an integrated circuit disposed on the substrate vertically from both ends of the suspended solenoid inductor including the fourth metal layer, the second supporting bars, and the bar-shaped third metal layer, for supporting the suspended solenoid inductor; and
any one among the substrate below the first supporting bar, the substrate and the bottom metal layer on the substrate, the substrate and a bottom ground metal layer on the substrate, the substrate and a patterned bottom ground metal layer on the substrate, the substrate, the bottom metal layer on the substrate and the bottom ground metal layer on the substrate, and the substrate, the bottom metal layer on the substrate and the patterned bottom ground metal layer on the substrate,
wherein turns of the suspended solenoid inductor including the fourth metal layer, the second supporting bar, the third metal layer and the first supporting bar are not connected in a single strand, but are divided into two strands of a first turn and a secondary turn, the first turn and the secondary turn being alternatively wound to each other.

30. A three-dimensional spiral transformer comprising:
a fourth metal layer suspended in a spiral shape;
two second supporting bars connected with an underlying first supporting bar vertically from both ends of the fourth metal layer, for supporting the fourth metal layer suspended in the spiral shape;
a third metal layer disposed below the fourth metal layer and suspended in the spiral shape;
two first supporting bars connected with a underlying substrate, a bottom metal layer or an integrated circuit disposed on the substrate vertically from both ends of the third metal layer suspended in the spiral shape, for supporting the third metal layer;
the two first supporting bars vertically connected with the underlying substrate, the bottom metal layer, or the integrated circuit disposed on the substrate, for supporting the two second supporting bars; and
any one among the substrate below the first supporting bar, the substrate and the bottom metal layer on the substrate, the substrate and a bottom ground metal layer on the substrate, the substrate and a patterned bottom ground metal layer on the substrate, the substrate, the bottom metal layer on the substrate and the bottom ground metal layer on the substrate, and the substrate, the bottom metal layer on the substrate and the patterned bottom ground metal layer on the substrate.

31. A three-dimensional transmission line comprising:
a transmission line made of a suspended third metal layer;
two first supporting bars connected with an underlying substrate, a bottom metal layer, or an integrated circuit disposed on the substrate vertically from both ends of the suspended transmission line, for supporting the suspended transmission line; and
any one among the substrate below the first supporting bar, the substrate and the bottom metal layer on the substrate, the substrate and the integrated circuit on the substrate, and the substrate, the integrated circuit on the substrate, and the bottom metal layer on the integrated circuit.

32. The three-dimensional transmission line of claim 31, further comprising a bottom ground metal layer or a patterned bottom ground metal layer on the substrate disposed below the suspended three-dimensional transmission line.

33. The three-dimensional transmission line of claim 31, further comprising two first ground walls formed to the substrate or an upper portion of the bottom metal layer from both sides spaced apart from the suspended transmission line.

34. The three-dimensional transmission line of claim 33, further comprising a first ground wing connected with an upper portion of the first ground wall and formed at the same layer as the suspended transmission line.

35. The three-dimensional transmission line of claim 32, further comprising two first ground walls formed to the substrate or an upper portion of the bottom metal layer from both sides spaced apart from the suspended transmission line.

36. The three-dimensional transmission line of claim 35, further comprising a first ground wing connected with an upper portion of the first ground wall and formed at the same layer as the suspended transmission line.

37. The three-dimensional transmission line of claim 33, further comprising a second ground wall disposed on the first ground wall and having the same structure as the first ground wall.

38. The three-dimensional transmission line of claim 35, further comprising a second ground wall disposed on the first ground wall and having the same structure as the first ground wall.

39. The three-dimensional transmission line of claim 38, further comprising a second ground wing for covering the two second ground walls and thus connecting the two second ground walls such that all portions except for both ends of the suspended transmission line are completely covered with a ground metal.

40. The three-dimensional transmission line of any one of claims 31-39, further comprising a solenoid-shaped ground wire disposed at the surrounding of the three-dimensional transmission line.

41. A three-dimensional micromirror comprising:
a suspended metal mirror plate;
at least one first supporting bar connected with an underlying substrate, a bottom metal layer, or an integrated circuit disposed on the substrate vertically from a predetermined region of the suspended metal mirror plate, for supporting the metal mirror plate;
any one among the substrate below the first supporting bar, the substrate and the bottom metal layer on the substrate, the substrate and the integrated circuit on the substrate, and the substrate, the integrated circuit on the substrate, and the bottom metal layer on the integrated circuit; and
at least one electrode metal layer formed in a predetermined shape on the substrate disposed below the suspended metal mirror plate.

42. A three-dimensional inductor model comprising:
a first port of which one end is grounded;
a second port of which one end is grounded;
resistance (R) and inductance (L) components connected in series between the other ends, which are not grounded in the first port, and the second port;
a fringe capacitance (Cf) component connected between the other ends, which are not grounded in the first port, and the second port;
a Cs capacitance component connected between the grounded one end of the first port and the other end which is not grounded in the first port; and
the Cs capacitance component connected between the ground one end of the second port and the other end, which is not grounded in the second port.

43. The three-dimensional inductor model of claim 42, wherein the Cs capacitance component has an air or a sealant as a medium.
